(19) United States
(12) Patent Application Publication
(10) Pub. No.: US 2019/0168445 A1
(43) Pub. Date: Jun. 6, 2019

(54) MANUFACTURING PROCESS OF A POSITIONING CONTROL TOOL VIA 3D-PRINTING TECHNOLOGY

(71) Applicant: AIRBUS OPERATIONS S.L., Madrid (ES)

(72) Inventors: Alvaro JARA RODELGO, Madrid (ES); Alvaro TORRES SALAS, Madrid (ES); Elena MOYA SANZ, Madrid (ES); Paloma LLORENTE GARCIA, Madrid (ES)

(21) Appl. No.: 16/205,578

(22) Filed: Nov. 30, 2018

(30) Foreign Application Priority Data
Dec. 1, 2017 (EP) 17382812.0

(51) Int. Cl. B29C 64/118; H01L 41/317; H01L 41/113; H01L 41/047; H01L 41/29; H05K 3/00; H05K 3/12; B33Y 10/00; B33Y 70/00; B33Y 80/00; B33Y 30/00; G01C 19/5698

(52) U.S. Cl. CPC B29C 64/118; B29K 2067/046; H01L 41/1132; H01L 41/0475; H01L 41/29; H05K 3/0014; H05K 3/1275; B33Y 10/00; B33Y 70/00; B33Y 80/00; B33Y 30/00; G01C 19/5698; H05K 2203/0126; H05K 2203/107; H05K 2203/163; H01L 41/317

(57) ABSTRACT

A manufacturing process to form a positioning control tool, such as a gyroscope, by using a three-dimensional (3D) printer printing a polymer material mixed with powdered graphene (12a) components (410) on a piezoelectric substrate (205), the components (410) include: a resonator (411) transducer configured to create a first surface acoustic wave (215); a pair of reflectors (412a, 412b) configured to reflect the first surface acoustic wave (215); a structure (413) which, when subjected to a Coriolis force, creates a second surface acoustic wave (230); a first sensor transducer (414) configured to sense the second surface acoustic wave (230); and a second sensor transducer (415) configured to sense a residual surface acoustic wave from a second region of the surface (210) of the piezoelectric substrate free of the structures that respond to the Coriolis force.

### RELATED APPLICATION

This application claims priority to European Patent Application 17382812-0 filed Dec. 1, 2017.

### FIELD OF THE INVENTION

The present invention relates to a smart tool and a manufacturing process to form a smart tool. More specifically, the invention relates to a manufacturing process that uses three-dimensional printing to form a smart positioning control tool, such as a gyroscope.

### BACKGROUND

Examples of a smart tools are gyroscopes and other navigational and sensing instruments. Gyroscopes are well known and used to measure and maintain orientation and angular velocity of a vehicle or other device. Gyroscopes are found in ships, aircraft, spacecraft, bicycles and other vehicles, as well as in mobile phones, joysticks, goggle glass, robots and other applications.

In a mechanical gyroscope, a stable reference vibrating motion (V) of a mass (m), such as an angular rotation (Ω) perpendicular to the direction of the vibrating motion (V), creates a Coriolis force (F) perpendicular to the directions of both the vibrating motion (V) and the angular rotation (Ω), at the frequency of the vibrating motion (V). The Coriolis force (F) may be measured and used to calculate the angular rotation (Ω) based on the mathematical relationship F=2(m)(V×Ω).

A mass constrained in a gyroscope by a stiffness element in a frame may be placed into an oscillatory motion in a z-direction by an input power source. If the frame is rotated about an x-axis, the oscillating mass will experience a Coriolis force, in a y-direction, proportional to the applied rate of rotation. The Coriolis force acts on the mass in an attempt to cause a displacement of the mass in the y-direction proportional to the rate of rotation.

A conventional MEM (Micro-Electro-Mechanical) gyroscope is a silicon-based vibratory sensor that utilizes an energy transfer between two vibrating modes of a mechanical structure. To achieve high sensitivity when subjected to a rotation, the energy from the vibrating modes must be efficiently transferred at a high Q level from exciting direction to a sensing direction. Considerable effort is required to design and fabricate the vibrating structure and its support electronics to achieve a resolution of less than one degree per second.

Conventional MEM gyroscopes suffer from an inherent performance limitation because of their underlying operating principle, which is based on a vibration of suspended mechanical structure, which is a comb structure, a beam, a disk, or a ring structure. It is often difficult and expensive to design and fabricate such a mechanical structures with matching resonant frequencies of the two vibrating modes. To improve the dynamic range of the gyroscope, the costs of electronic circuitry for controlling and detecting the status of the vibrating structure may be relatively high.

In addition, the suspended vibrating mechanical structure is susceptible to external shock and vibration that occurs at frequencies not far removed from the frequency at which the gyroscope operates. Such disturbances can influence the vibrating structure. Consequently, the structure cannot be rigidly attached to the substrate for its resonant vibration, thereby also limiting its dynamic range.

### SUMMARY OF THE INVENTION

The present invention may be embodied as a manufacturing process using 3D-printing technology to form a positioning control tool, such as a gyroscope. The process may include the following steps:

(i) 3D-print a first part of a frame on a print bed by printing an insulating 3D-printing polymer material. The frame may be a lid of a casing which mates with an opposing lid to form a casing to enclose components and electronics which may also be 3D printed.

(ii) 3D-print a set of layers of piezoelectric substrate inside the first part of frame with a polymer printing material mixed with powdered graphene inside the first part of frame;

(iii) 3D-print a pattern having a plurality of apertures therethrough;

(iv) 3D-print with a polymer printing material mixed with powdered graphene, using the pattern, a plurality of components on the substrate, the components comprising:

(a) a resonator transducer for creating a first surface acoustic wave on the surface of the piezoelectric substrate;

(b) a pair of reflectors for reflecting said first surface acoustic wave to form a standing wave within a first region of said surface between said pair of reflectors;

(c) a structure within the first region, wherein a Coriolis force acting upon the structure creates a second surface acoustic wave;

(d) a first sensor transducer disposed on the first surface for sensing said second surface acoustic wave; and

(e) a second sensor transducer disposed on the surface for sensing a residual surface acoustic wave from a second region of the surface that is free of any structure that the Coriolis force can act upon, and for providing an output indicative of said residual surface acoustic wave; and

(v) 3D-print a second part of frame with an insulating 3D-printing polymer material, such as to form a frame to protect and guaranty the working of the piezoelectric substrate with the features embedded.

### BRIEF DESCRIPTION OF THE DRAWINGS

To complete the description and to provide for a better understanding of the invention, a set of drawings is provided. Said drawings form an integral part of the description and illustrate preferred embodiments of the invention. The drawings comprise the following figures:

FIG. 1 is a schematic representation of main elements of 3D-printer;

FIG. 2 is a schematic representation an embodiment of a gyroscope according to the manufacturing process of the present invention; and

FIG. 3 is a schematic representation of an embodiment of the positioning control tool according to the invention;

### DETAILED DESCRIPTION OF THE DRAWINGS

The present invention is directed generally toward the manufacturing process of a positioning control tool. An exemplary embodiment of the invention is disclosed herein. A person skilled in the relevant art will understand that the invention may be have additional embodiments, and that the invention may be practiced without several of the details of the embodiment herein.

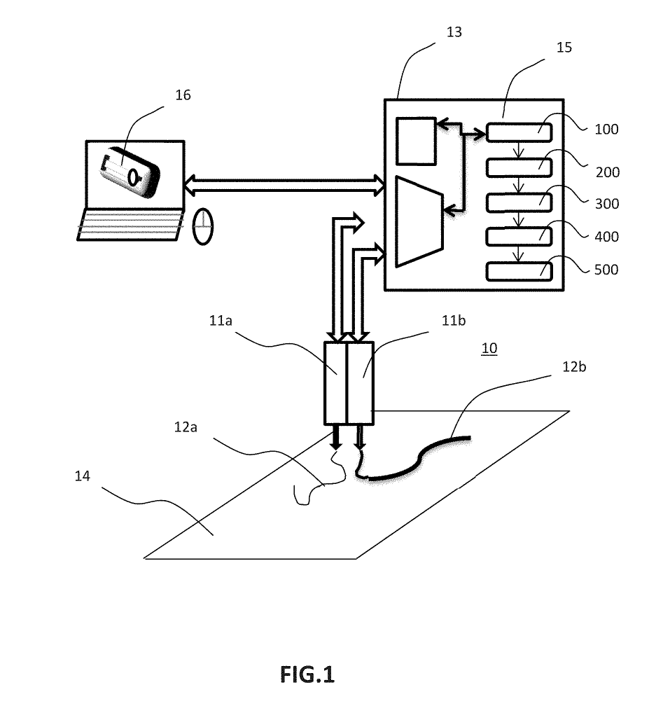

3D (three dimensional) printing, also known as additive layer manufacturing, is taking on increasing importance in many different industrial sectors. There are many applications of 3D printing, including manufacturing of tools, jigs, parts of simple or complex structure, each of which may be designed according a specific need. Manufacturing using 3D-printing technologies is used especially with Fused Deposition Modelling (FDM) as represented in FIG. 1.

The Fused Deposition Modelling (FDM), also called FFF (Fused Filament Fabrication) or PJP (Plastic Jet Printing), is an additive manufacturing technology. Additive manufacturing technology is commonly used for thermoplastics 3D-printing and includes modeling, prototyping and production applications. Additive manufacturing technology prints 3D parts by successively printing 2D (two dimensional) layers of uniform thickness. This successive 2D printing may be called 2.5D (2.5 dimensions), as there is no coordinated movement in a third dimension, e.g., the z-direction, of the successive 3D printing of the layers.

3D-printing material used in 3D printing includes a polymer base, which can be PLA (Polylactic Acid) or ABS (Acrylonitrile Butadiene Styrene). The polymer base may be powdered with graphene to modify some of its properties. Graphene is a nanomaterial that may be formed as a one-atom-thick planar sheet of bonded carbon atoms densely packed in a honeycomb crystal lattice. Graphene is a basic structural element of some variants carbon such as graphite, charcoal, nanotubes, and fullerenes.

Graphene has electronic and mechanical properties that may it attractive for use in 3D printing materials. These properties include:

(i) transparency and flexibility;

(ii) high thermal and electrical conductivity, and may be embodied to be more conductive than Cu (copper) or Ag (silver);

(iii) high elasticity and hardness;

(iv) low weight. such as on the order of the weight of carbon fiber and more flexible than carbon fiber; and

(v) allows electrons to flow faster than through silicon.

Adding graphene to 3D print materials increases the potential applications which may be formed by 3D-printing.

Graphene has opened new ways and new applications for the manufacturing of electronic components. These applications include sheet active or passive electronic components with graphene, such as semi-conductors, dielectric-interfaces, piezoelectric substrate, transistors, integrated circuits, OLED displays, or organic photovoltaic cells.

To take advantage of the state of the art of 3D printing described above, there is a need to develop a smart device or tool with the 3D-printing technology. The invention disclosed herein is such a smart device or tool.

FIG. 1 shows a 3D-printer 10, able to manufacture a positioning control tool. The 3D printer 10 includes a first 3D-printing head 11a to selectively discharge a conductive 3D-printing material 12a and a second 3D-printing head 11b to selectively discharge an insulating 3D-printing material 12b. The 3D printing materials are printed on a print bet 14 or on previously printed layers of the 3D printing materials.

The 3D-printer 10 includes a computer processor 13 configured to control the printing operations of the first and second 3D-printing heads 11a, 11b. The processor 13 of the 3D-printer 10 is able to execute steps 15 of a computer program stored in the 3D printer and/or accessible by the processor. The steps 15 include instructions for a CAD (Computer-Aided Design) scheme 16 describing a multi-layer printed circuit board (PCB) intended for 3D-printing.

Each 3D-printing head 11a, 11 b is able to print in X and Y directions for each layer of conductive 3D printing material or insulating (dielectric) 3D-printing material. Each 3D-print heads 11a, 11 b or a print bed 14 moves as printed material is printed onto a print table. The print table is mounted to the print bed 14. For each layer of the printed component, the print heads 11a, 11 b and/or the print bed/table move as print material 12a, 12b is printed. Typically, a layer will be completed printed before a subsequent layer is printed.

The print material 12a, 12b may be a thermoplastic filament or wire that is heated pass its glass transition temperature and then printed on the print bed 14 or table. The printed material cools and consolidates with and on layers of printed material previously printed to create a solid part.

The first and second 3D-printing heads 11a, 11 b are configured to 3D-print a functional passive and/or active electrical component, a piezoelectric sensor, piezoelectric substrate, wafer, a functional resistor, a functional capacitor, a functional electromagnetic waveguide, a functional optical waveguide, a functional antenna or protruding antenna or horn antenna, a functional heat sink, a functional coaxial element or coaxial cable or coaxial mesh, a SMT or COB component, or equivalent. A SMT component is a Surface Mounted Technology component. Similarly, a COB component is a Chip-On-Board component assembly.

The first and the second 3D-printing heads 11a, 11b may be configured to 3D-print, during a 3D-printing session, a PCB (Printed Circuit Board) and an electrical component embedded within the PCB.

The first 3D-printing head 11a discharges conductive 3D-printing material 12b from 3D print nozzles, at the base of the arrow projecting from print head 1a, onto the print bed 14. A first of the 3D-printing nozzles is configured to discharge the conductive 3D-printing material through a first nozzle aperture having a first diameter. A second 3D-printing nozzle discharges the conductive 3D-printing material through a second nozzle aperture having a second diameter which is different than the diameter of the nozzle of the first printing nozzle. The first 3D printing head 11a may have one, two or more nozzles each having a different aperture.

The second 3D printing head 11b discharges the insulating print material 12b from one or more selectable nozzles. If there is more than one nozzle, the nozzles may have discharge apertures of different sizes.

The nozzles in the first and second 3D printing heads are selectable such that material may be printed from the one or more selected nozzle while no material is discharged from the unselected nozzles. To switch between the print nozzles in the first 3D printing head 11a, the 3D-printer 10 includes a switching module, such as a software module in a computer controller, to selective and activate a nozzle(s) during a 3D-print session.

The 3D-printer 10 may include additional modules which may be used alone or in combination with other modules during a print session. This following list of additional modules need not be exhaustive and the modules in an embodiment of the printer 10 may be selected to meet the needs and requirements of the intended application(s) for the printer.

The 3D-printer 10 may include an ultraviolet (UV) energy-based curing module which is configured to emit ultraviolet (UV) radiation to cure printed 3D-materials region-by-region as the 3D-printed materials are being 3D-printed. The UV radiation may be shined over the entire print table at selected periods or may be focused on certain regions of the print table and printed layers. The certain regions may be selected by directing the UV radiation to the regions, wherein the direction is controlled by a control system of the printer 10.

The 3D-printer 10 may comprise a laser source to emit a laser beam for curing 3D-printed materials. A controller for the laser source and laser beam region-by-region when the 3D-printed materials are being 3D-printed. The controller may be a software application executed by the processor 13 or the controller may be a separate computer controller dedicated to controlling the laser(s). The controller may direct the laser beam to the region of the printed material to be cured. Similarly, the 3D-printer 10 may include a laser source which emits a laser beam at a target site at or immediately adjacent the most recently printed 3D material to cure the material in near real time with the printing of the material.

The 3D-printer 10 is may be configured to transition between two crossed conductive materials, with the following sequential 3D-printing steps (which may be included in the steps 15 executed by the processor):

(i) printing a first trace of a conductive material 12a from a nozzle of the first print head 11a, wherein printing includes curing the material;

(ii) form a bridge over a selected site of the first trace by printing insulating material 12b from a nozzle of the second print head 11b, wherein printing includes curing the material; and

(iii) printing, over the bridge, a second trace of conductive material 12a from a nozzle of the first print head 11a, wherein printing includes curing the material.

The 3D-printer 10 may include an Automatic Optical Inspection (AOI) module configured to sequentially:

(i) capture an image of a 3D-printed conductive trace during an ongoing 3D-printing session;

(ii) compare the captured image of the 3D-printed trace to a reference image indicating a required width of the 3D-printed conductive trace;

(iii) based on the comparison, determine whether a width of at least a portion of the 3D-printed conductive trace is smaller than the required width and identify a portion of the 3D printed conductive trace that is too narrow; and

(iv) trigger a corrective 3D-printing operation to add printed conductive material to the identified portion of the 3D conductive trace to increase the width of the identified portion of the 3D-printed conductive trace.

The AOI module and other modules disclosed herein may be, which may be software modules incorporated in the steps 15 executed by the processor 15,

Similar corrective steps (i) to (iv) may be performed to add insulating printed material to portions of traces of the insulating printed material that are identified as being too narrow.

The 3D-printer 10 may comprise an Automatic Optical Inspection (AOI) module configured to sequentially:

(i) capture an image, in near real time, of a printed trace of the 3D-printed conductive material 12a by the first print head 11a, during an ongoing 3D-printed session.

(ii) compare the captured image of the printed trace to a reference indicating a required width of the 3D-printed conductive trace;

(iii) based on the comparison, determine whether a width of some portion of the 3D-printed conductive trace is greater than the required width and identified the portion having a width greater than required;

(iv) active a laser ablation module to direct a laser to the edges of the 3D printed conductive trace for the portion having a width greater than required and applying the laser to narrow the width of the 3D-printed conductive trace along the identified portion.

Similar corrective steps (i) to (iv) may be performed to narrow traces of the insulating printed material

The 3D-printer 10 may include an Automatic Optical Inspection (AOI) module that sequentially:

(i) captures in or near real time of an image of a 3D-printed conductive trace as the trace is being printed during an ongoing 3D-printing session;

(ii) compare the captured image of the 3D printed conductive trace to a reference image indicating a required structure of the 3D-printed conductive trace;

(iii) based on the comparison of the captured image and the reference image, identify a fracture, e.g., break, in the 3D-printed conductive trace; and

(iv) trigger a corrective 3D-printing operation in which 3D-conductive material 12a is printed from the first print head 11a onto the identified fracture area.

Similar corrective steps (i) to (iv) may be performed for fractures in traces of the insulating printed material.

The 3D-printer 10 may include an Automatic Optical Inspection (AOI) module configured to sequentially:

(i) capture an image of a 3D-printed pad of conductive print material 12a printed by the first print heat 11a during an ongoing 3D-printing session during which is formed a 3D-printed PCB;

(ii) compare the captured image of the 3D printed pad to a reference indicating a required structure of the 3D-printed pad;

(iii) based on the comparison, determine whether the 3D-printed pad is excessively large;

(iv) trigger a laser ablation module to decrease the area of the 3D-printed pad by applying a laser to an edge(s) of the 3D printed pad and thereby removing a region(s) of the 3D printed pad and reducing the area of the 3D printed pad.

Similar corrective steps (i) to (iv) may be performed to contour a 3D printed pad of an insulating material.

The 3D-printer 10 may include a solder mask 3D-printing module configured to 3D-print a solder mask with conductive material 12a on a 3D-printed PCB, wherein the solder mask and the PCB are 3D-printed in a single, unified, 3D-printing process.

The 3D-printer 10 may include a heat sink 3D-printing module to 3D-print a thermally-conductive heat sink integrated in a pre-defined region of a 3D-printed PCB being 3D-printed.

The 3D-printer 10 may include a thermal conductivity planner configured to:

(i) determine whether a selected region of a PCB which will be below a 3D-printed conductive pad requires a heat transfer path with increased thermal conductivity;

(ii) if a heat transfer path is required, 3D-print on the region which will below the 3D-printed conductive pad a first 3D-printing material having increased thermal conductivity relative to a second 3D-printing material used for 3D-printing at a surrounding region of the pad which does not require a heat transfer path with increased thermal conductivity, and

(iii) 3D printing the conductive pad over the selected region and the heat transfer path.

The 3D-printer 10 may include a thermal conductivity planner configured to:

(i) determine whether a particular region of a PCB being 3D-printed requires a heat transfer path with increased thermal conductivity and identify the particular region; and

(ii) 3D-print on the particular region of the PCB conductive print material 12a with the first print head 11a an electrically conductive path extending from the particular region to a 3D-printed heat sink at a bottom or lower layer of said PCB being 3D-printed.

The 3D-printer 10 may include an embedded SMT component 3D-printing module configured to 3D-print a 3D-printed PCB having a fully-buried (unexposed 3D-printed Surface-Mount Technology (SMT) component.

The 3D-printer 10 may include a pause-and-resume 3D-printing controller configured to:

(i) pause a 3D-printing process of a PCB being 3D-printed, and

(ii) wait until a COB/SMT component is assembled on an already-3D-printed portion of the PCB on top of the COB/SMT that was 3D-printed.

The 3D-printer 10 may include a module configured to modify the width and/or thickness of a trace of 3D conductive printed material during a 3D-printing process of a conductive trace, wherein at least one of: a width of the constructive trace are being 3D-printed, and a thickness of the conductive trace are being 3D-printed; wherein the module is configured to modify the width and/or thickness of the conductive trace while maintaining a fixed current-carrying capacity of the conductive trace.

The 3D-printer 10 may comprise a module configured to modify the rigidity and/or flexibility of a 3D PCB being printed to conform to requirements of changing levels of rigidity and/or flexibility of the PCB, wherein the requirements may include a gradual or abrupt change in rigidity and/or flexibility.

The 3D-printer 10 may include a module configure to modify a dielectric material thickness in response to process steps executed by the 3D-printer 10 to 3D-print a dielectric material layer and/or trace having a varying thickness. The dielectric material layer and/or trace may be between and separate a first 3D-printed conductive layer and a second, neighboring, non-parallel, 3D-printed conductive layer.

The 3D printer 10 may be configured to 3D-print a conductive material to create a three-dimensional structure of a first layer of a PCB and a second, non-parallel, layer of the PCB.

The 3D-printer 10 may be configured to 3D-print a positioning control tool. In order to manufacture that, the manufacturing process comprises the following steps in order to form a gyroscope:

(i) 3D-print, based on instruction steps 100, a first part of a frame 110 wherein the printing is of insulating print material 12b to form a recipient led on the print bed 14,

(ii) 3D-print, based on instruction steps 200, layers to form a piezoelectric substrate 205 on an inside surface of a first part of frame 110 by printing a polymer print material mixed with powdered graphene to form a conductive printed layer;

(iii) 3D-print, based on instructions 300, a printed pattern 310 having a plurality of apertures 320 therethrough. The printed pattern 310 may be 3D printed from the second print heat 11b by applying 3D insulating material 12b to form an insulating layer or pad. The apertures 320 in the insulating layer or pad may receive the electronic components 410;

(iv) 3D-print 400 with a polymer material mixed with powdered graphene 12a, using the pattern 310, components 410 on the piezoelectric substrate 205. These components are formed of conventional electronic components, such as resistors, capacitors, diodes, transistors, and may have structures that are conventional and well known electronic components. The components may are formed by 3D printing including printing a conductive 3D print material 12b that includes powdered graphene.

The components 410 include:

(a) a resonator transducer 411 configured to create a first surface acoustic wave 215 on the surface 210 of the piezoelectric substrate 205;

(b) a pair of reflectors 412a, 412b configured to reflect the first surface acoustic wave 215 to form a standing wave within a first region 220 of the surface 210 and between the reflectors 412a, 412b;

(c) a structure 413 within the region 220, wherein a Coriolis force acting upon the structure 413 creates a second surface acoustic wave 230, wherein the structure 413 may be a comb structure, a beam, a disk, or a ring structure. The structure 413 may be formed in an aperture 320 in the piezoelectric substrate. The structure 413 may include multiple structures 413 at orthogonal orientations. The structure(s) 413 vibrate in response to a Coriolis force and induce vibration on the surface of the piezoelectric substrate 205;

(d) a first sensor transducer 414 disposed on the surface 210 and configured to sense the second surface acoustic wave 230, and

(e) a second sensor transducer 415 disposed on the surface 210 and configured to sense a residual surface acoustic wave from a second region of the surface 210, wherein the second region is free of any structure that is acted upon by a Coriolis force. The second transducer generates an output signal indicative of the residual surface acoustic wave; and

(v) 3D-print, based on instruction steps 500, a second part of the frame 510 with a printed insulating polymer material 12b to form a complete frame to enclose, protect and guaranty the working of the piezoelectric substrate 205 with the components 410 printed on the substrate 204.

The above-described embodiment may be formed by ALM (Additive Laser Manufacturing) to manufacture/3D-print quickly any simple or complex piezoelectric substrate 205, patterns 310, components (features) 410, and/or frames 110, 510 according to an ad-hoc design. Another advantage of this embodiment is the possibility to modify the shape or restyle partially or totally the frame 110, 510.

The polymer material used to manufacture the positioning control tool may be a base of PLA (Polylactic Acid) or ABS (Acrylonitrile Butadiene Styrene).

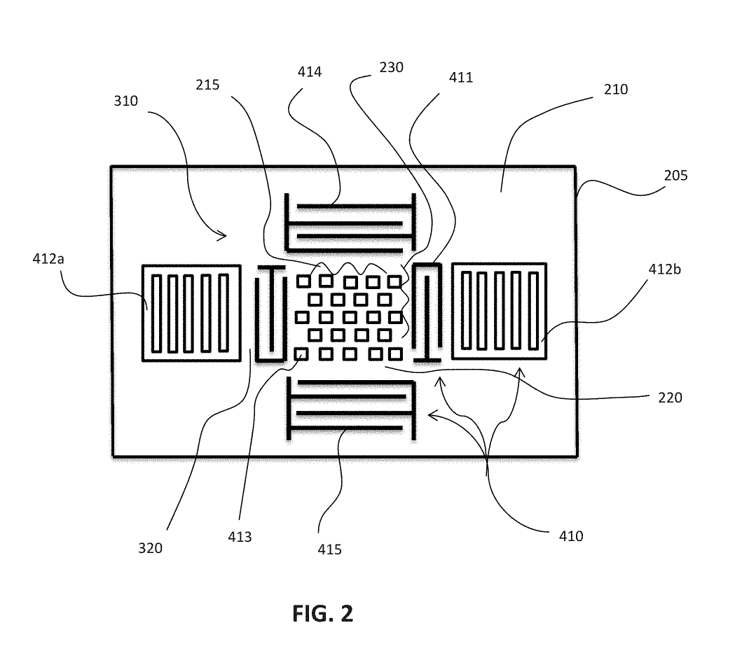

FIG. 2 shows a gyroscope including a piezoelectric substrate 205 and components 400 that include a pair of resonator transducers 411a, 411b, a pair of reflectors 412a, 412b, at least one structures 413 subject to a Coriolis force, and a pair of sensory transducers 414, 415.

The piezoelectric substrate 205 has a surface 210 upon which the other components 410 of the gyroscope are printed. The pair of resonator transducers 411a, 411b are arranged on the surface 210 to create the first surface acoustic wave 215 on the surface 210. More particularly, the pair of resonator transducers 411a, 411b create an electrical potential on the substrate 205, and the piezoelectric substrate 205 converts the electrical potential into mechanical energy, thus forming the first surface acoustic wave 215. The resonator transducers 411a, 411b have fingers (as shown in FIG. 2) spaced with a periodicity of half of the wavelength of the first surface acoustic wave 215.

The pair of reflectors 412a, 412b, is disposed on the surface 210 for reflecting the first surface acoustic wave 215 to form a standing wave within a region 220 of the surface 210, which is located between the pair of reflectors 412a, 412b. The reflectors are separated from each other by a distance that is an integral number of one half wavelengths of the first surface acoustic wave.

The structure 413 comprises a set of elements disposed on the surface 210 within region 220. A Coriolis force acting upon the set of elements of the structure 413 creates a plurality of second surface acoustic waves 230.

A pair of sensor transducers 414, 415 is disposed on the surface 210, separated together and disposed orthogonally to the pair of resonator transducers 411a, 411b for sensing the second surface acoustic wave and providing an output indicative of the characteristic of the second surface acoustic wave.

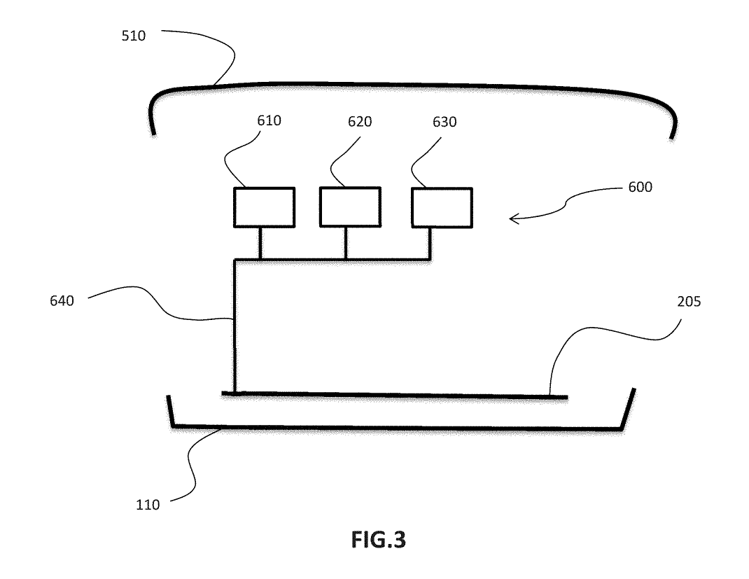

FIG. 3 shows the positioning control tool electrically connected 640 to a circuit board 600 3D which is also-formed by 3D printing. The circuit board may be partially or totally embedded within the first part 110 or the second part 510 of the frame.

The circuit board 600 includes:

(i) a set of sensors 610 connected to the components 410 of the gyroscope on the piezoelectric substrate 205 via conductive printed trace 640. The sensors 610 measure output signals from the sensor transducers 414, 415 which signals are indicative of the angular movement of structures 413 in the gyroscope;

(ii) a set of digital and/or analogic components 620 configured to process and analyze the digital or analogic signals generated by the set of sensors 610, wherein these signals are indicative of the angular movement of the structures 413;

(iii) at least one IHM (Interface Human Machine) 630 able to allow to a human operator interact or a computer system to automatically interact with the sensors 610 and/or the components 620; and

(iv) at least one conductive trace 640, e.g., bus, configured to connected to the set of sensors 610 to the gyroscope components 410 and to the set of digital and/or analogic components 620, and at least one IHM 630.

An advantage of this embodiment is to confer some smart properties to the positioning control tool, such as a gyroscope, to allow for interactions between the tool and an operator or a computer system. The operator or the computer system may interact directly or indirectly with the positioning control tool via an IHM or other communication system.

At least one component of the set of digital and/or analogic components 620 may be manufactured via 3D printed graphene.

At least one component 620 may be a 3D printed Surface-Mount Component (SMT) or a Chip On Board (COB);

The positioning control tool may include a 3D printed antenna. The 3D-printed antenna may be a RFID (Radio Frequency Identification). An advantage of a RFID antenna is the ability to transmit, receive and store remote data quickly to a humanoid or an automaton able to communicate with said positioning control tool.

The conductive trace 640 may have a thermal conductivity or is able to conduct electricity. The 3D-printer 10 is able to add more or less graphene powder in the conductive material 12a to obtain a trace 640 with a better thermal or electricity conductivity.

The IHM 630 may be a buzzer, and/or a display interface such as LCD or a set of Led to interact easily with the human operator; In the case of the humanoid or automaton, the communication means are more useful in order to have an interaction with the positioning control tool.

The operator is a human or humanoid entitled and able to handle with his hand said positioning control tool. By automaton we understand a self-operating machine, or a machine, or a control mechanism designed to automatically follow a predetermined sequence of operations, or respond to predetermined instructions.

The positioning control tool may include a battery that provides electrical power to all components 410 of the tool, e.g., gyroscope, and associated electronics 600, such as the set of sensors 610, the set of digital and/or analogic components 620, and the set of IHM 630. The battery may be rechargeable.

From the foregoing, it will be appreciated that specific embodiments of the invention have been described herein for purposes of illustration, but that various modifications may be made without deviating from the spirit and scope of the invention. For example, aspects of the invention described in the context of particular embodiments may be combined or eliminated in other embodiments. Although advantages associated with certain embodiments of the invention have been described in the context of those embodiments, other embodiments may also exhibit such advantages. Additionally, none of the foregoing embodiments need necessarily exhibit such advantages to fall within the scope of the invention. Accordingly, the invention is not limited except as by the appended claims.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

The invention is:

1. A method to 3D print a gyroscope, wherein the method includes:
3D print an insulating 3D-printing polymer material to form a first part of a frame for the gyroscope;
3D print a polymer material mixed with powdered graphene on the first part of the frame to form a piezoelectric substrate;
3D print a pattern on the piezoelectric substrate, wherein the pattern has apertures;
3D print a polymer material mixed with powdered graphene to form components on the piezoelectric substrate and using the pattern, wherein the printed components include:
a resonator transducer configured to create a first surface acoustic wave on a surface of the piezoelectric substrate;
a pair of reflectors configured to reflect the first surface acoustic wave to form a standing wave within a first region of the surface and between the pair of reflectors;
a structure within the first region wherein the structure is subject to a Coriolis force to create a second surface acoustic wave on the piezoelectric substrate;
a first sensor transducer disposed on the surface and configured to sense the second surface acoustic wave; and
a second sensor transducer disposed on the surface and configure to sense a residual surface acoustic wave from a second region of the surface, wherein the second region is separated form the structure, and the second sensor is configured to output a signal indicative of the residual surface acoustic wave; and
3D print insulating 3D printing polymer material to form a second part of the frame, wherein the second part and first part of the frame are assembled together to form the frame which supports the printed components and the piezoelectric substrate.

2. The method according to claim 1, further comprising modifying a design of the first part or the second part of the frame prior to the printing of the first part or the second part.

3. The method of claim 1, wherein the polymer material includes Polylactic Acid and/or Acrylonitrile Butadiene Styrene.

4. The method of claim 1, further comprising 3D printing a circuit board partially or totally embedded within or on a surface of the first part or the second part of the frame.

5. The method of claim 4, wherein the circuit board includes:
a set of sensors configured to be connected to the gyroscope to receive signals from at least one of the first and second sensor transducers;
a set of digital and/or analogic electronic components configured to respectively analyze digital or analogic signals from the set of sensors;
at least one Interface Human Machine configured to enable the a human operator and/or a computer system to communicate with the set of sensors; and
at least one conductive trace conductively connecting the set of sensors, the set of digital and/or analogic components, and the at least one Interface Human Machine.

6. The method of claim 5, wherein the at least one of the set of digital and/or analogic components are formed by 3D printing of a polymer material mixed with powdered graphene.

7. The method of claim 6, wherein the at least one of the set of digital and/or analog components is a 3D-printed Surface-Mount Component (SMT).

8. The method of claim 5, further comprising 3D printing an antenna on one of the first part or the second part of the frame.

9. The method of claim 8, wherein the antenna is an antenna for a Radio Frequency Identification device.

10. The method of claim 5, wherein that the at least one conductive trace has a thermal conductivity and/or electrical conductivity.

11. The method of claim 5, wherein the at least one Interface Human Machine is a buzzer and/or a display device.

12. A method to make an instrument with a gyroscope, wherein the method includes:
printing, by a three-dimensional (3D) printer, an insulating polymer material to form a first part of a frame;
printing, by the 3D printer, a polymer material mixed with powdered graphene on a surface of the first part of the frame to form a piezoelectric substrate;
printing, by the 3D-printer, an insulating layer on the piezoelectric substrate wherein the insulating layer is printed in a pattern which has apertures in the insulating layer;
printing, by the 3D-printer, a polymer material mixed with powdered graphene to the gyroscope wherein the printed components of the gyroscope include:
a resonator transducer configured to create a first surface acoustic wave on the piezoelectric substrate;
a pair of reflectors configured to reflect the first surface acoustic wave to form a standing wave within a first region on the piezoelectric substrate and between the pair of reflectors;
a structure within the first region wherein the structure vibrates in response to a Coriolis force to create a second surface acoustic wave on the piezoelectric substrate;
a first sensor transducer disposed on the piezoelectric substrate and configured to sense the second surface acoustic wave; and
a second sensor transducer disposed on the piezoelectric substrate and configure to sense a residual surface acoustic wave from a second region of the piezoelectric substrate, wherein the second region is separated from the first region, and the second sensor is configured to output a signal indicative of the residual surface acoustic wave;
wherein at least one of the components is at least partially printed into one of the apertures of the pattern of the insulating layer, and
printing, by the 3D printer, and the insulating polymer material a second part of the frame, wherein the second part and first part are assembled together to form the frame which supports the piezoelectric printed components and the piezoelectric substrate.

13. The method of claim 12, wherein the printing steps are performed with a three-dimensional printer.

14. The method of claim 12, further comprising printing a circuit board with electronic components on one of the first and second parts of the frame.

15. The method of claim 14 wherein the electronic components include:
a sensor configured to be connected to the gyroscope to detect signals from the first and/or second sensor transducers;
a electronic analyzer configured to respectively analyze signals from the sensor;
an Interface Human Machine configured to enable the a human operator and/or a computer system to communicate with the set of sensors; and
a conductive trace conductively connecting the sensor, the electronic analyzer, and the Interface Human Machine.
